(19) United States
(12) Patent Application Publication
(10) Pub. No.: US 2023/0115122 A1
(43) Pub. Date: Apr. 13, 2023

(54) METHOD OF BONDING THIN SUBSTRATES

(71) Applicant: ADEIA SEMICONDUCTOR BONDING TECHNOLOGIES INC., San Jose, CA (US)

(72) Inventors: Cyprian Emeka Uzoh, San Jose, CA (US); Thomas Workman, San Jose, CA (US); Gabriel Z. Guevara, San Jose, CA (US); Dominik Suwito, San Jose, CA (US); Guilian Gao, San Jose, CA (US)

(21) Appl. No.: 17/931,826

(22) Filed: Sep. 13, 2022

Related U.S. Application Data
(60) Provisional application No. 63/244,091, filed on Sep. 14, 2021.

(51) Int. Cl. H01L 21/762; H01L 21/786; H01L 21/321; H01L 21/02

(52) U.S. Cl. CPC H01L 21/76202; H01L 21/786; H01L 21/3212; H01L 21/02348

(57) ABSTRACT

Methods of bonding thin dies to substrates. In one such method, a wafer is attached to a support layer. The wafer and support layer are attached to a dicing structure and then singulated to form a plurality of semiconductor die components. Each semiconductor die component comprises a thinned die and a support layer section attached to the thinned die where each support layer section is disposed between the corresponding thinned die and the dicing structure. At least one of the semiconductor die components is then bonded to a substrate without an intervening adhesive such that the thinned die is disposed between the substrate and the support layer section. The support layer section is then removed from the thinned die.

### PRIORITY APPLICATION

This application claims the benefit U.S. Provisional Application No. 63/244,091 filed on Sep. 14, 2021, which is incorporated herein by reference. Any and all applications for which a foreign or domestic priority claim is identified in the Application Data Sheet as filed with the present application are hereby incorporated by reference under 37 CFR 1.57.

### BACKGROUND OF THE TECHNOLOGY

### Field

The field relates to methods and systems of bonding thin substrates.

### Description of Related Art

Microelectronic elements often comprise a thin piece of a semiconductor material, such as silicon or gallium arsenide, commonly called a semiconductor wafer. A wafer can be formed to include multiple integrated chips or dies on a surface of the wafer and/or at least partially embedded within the wafer. Dies that are separated from a wafer are commonly provided as individual, prepackaged units. In some package designs, the die is mounted to a substrate or a chip carrier, which is in turn mounted on a circuit panel, such as a printed circuit board (PCB). For example, many dies are provided in packages suitable for surface mounting.

Packaged semiconductor dies can also be provided in “stacked” arrangements, wherein one die is provided, for example, on a carrier, such as an interposer, a wafer, a die, a circuit board or any other suitable carrier, and another die is mounted on top of the first die. These arrangements can allow a number of different dies or devices to be mounted within a single footprint on the carrier and can further facilitate high-speed operation by providing a short interconnection between the dies. Often, this interconnect distance can be only slightly larger than the thickness of the die itself. For interconnection to be achieved within a stack of dies, interconnection structures for mechanical and electrical connection may be provided on both sides (e.g., faces) of each die package (except for the topmost package).

Additionally, dies or wafers may be stacked in a three-dimensional arrangement as part of various microelectronic packaging schemes. This can include stacking a layer of one or more dies, devices, and/or wafers on a base die, device, wafer, substrate, or the like, stacking multiple dies or wafers in a vertical or horizontal arrangement, and various combinations of both.

Dies or wafers may be bonded in a stacked arrangement using various bonding techniques, including direct dielectric bonding, non-adhesive bonding techniques (e.g., ZiBond®), or hybrid bonding techniques (e.g., DBI®). Both ZiBond® and DBI® bonding techniques are available from Invensas Bonding Technologies, Inc. (formerly Ziptronix, Inc.), an Xperi company (see for example, U.S. Pat. Nos. 6,864,585 and 7,485,968, which are incorporated herein in their entirety). Respective mating surfaces of the bonded dies or wafers often include embedded conductive interconnect structures, or the like. In some examples, the bonding surfaces are arranged and aligned so that the conductive interconnect structures from the respective surfaces are joined during the bonding. The joined interconnect structures form continuous conductive interconnects (for signals, power, etc.) between the stacked dies or wafers.

There can be a variety of challenges to implementing stacked die and wafer arrangements. Thin dies and wafer may sometimes be fragile and may be prone to breaking or deformation during processing, resulting in unintended yield losses. For example, when picking up a thin die to stack it on a substrate or another thin die, the pick-up tool and/or the bonding tool can inadvertently impart stresses onto the thin die. These stresses can cause the thin die to break or deform, and/or can introduce unwanted defects within the semiconductor substrate or one of its overlying dielectric layer. These unwanted defects may result in device yield losses in subsequent processing operations. The subsequent operations may comprise, for example, annealing the bonded thin dies at a temperature higher than the initial bonding temperature, stacking additional dies over the bonded thin dies, stressing the bonded dies, applying a mold layer over bonded dies, or operating the bonded structure at a customer site. Accordingly, there is a need for a method of placing thin dies on a substrate and stacking multiple thin dies together that does not cause the thin dies to break or deform, and that does not produce device yield loss in subsequent device-forming operations.

### SUMMARY

For purposes of summarizing the disclosure and the advantages achieved over the prior art, certain objects and advantages of the disclosure are described herein. Not all such objects or advantages may be achieved in any particular embodiment. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these embodiments are intended to be within the scope of the invention herein disclosed. These and other embodiments will become readily apparent to those skilled in the art from the following detailed description of the preferred embodiments having reference to the attached figures, the invention not being limited to any particular preferred embodiment(s) disclosed.

### BRIEF DESCRIPTION OF THE DRAWINGS

FIGS. 1A-1I depict a flow diagram of a method of attaching thin dies to a substrate, according to an embodiment of the present technology.

FIGS. 2A-2H depict a flow diagram of another method of attaching thin dies to a substrate, according to another embodiment of the present technology.

FIGS. 3A-3H depict a flow diagram of another method of attaching thin dies to a substrate, according to another embodiment of the present technology.

FIGS. 4A-4H depict a flow diagram of another method of attaching thin dies to a substrate, according to another embodiment of the present technology.

FIGS. 5A-5I depict a flow diagram of another method of attaching thin dies to a substrate, according to another embodiment of the present technology.

FIGS. 6A-6C depict a flow diagram of a method of stacking multiple thin dies to form a thin die stack, according to another embodiment of the present technology.

FIGS. 7A-7E illustrate example back side structures for thinned dies to be mounted to a support structure, according to various embodiments.

### DETAILED DESCRIPTION

There can be a variety of challenges to implementing stacked die and wafer arrangements. Thin dies and wafer may sometimes be fragile and may be prone to breaking or deformation during processing. For example, when picking up a thin die to stack it on a substrate or another thin die, the pick-up tool and/or the bonding tool can inadvertently impart stresses onto the thin die. These stresses can cause the thin die to break or deform or can introduce unwanted defects in the thin die. Accordingly, there is a need for a method of placing thin dies on a substrate and stacking multiple thin dies together that does not cause the thin dies to break or deform or that introduces undesirable device yield losses.

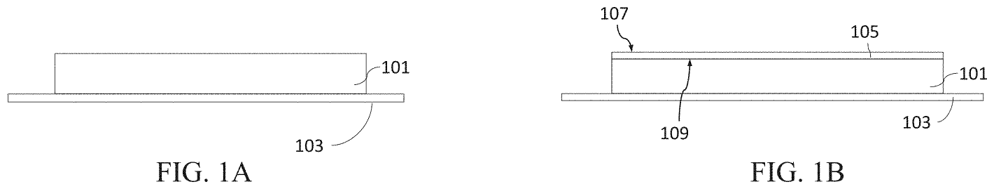

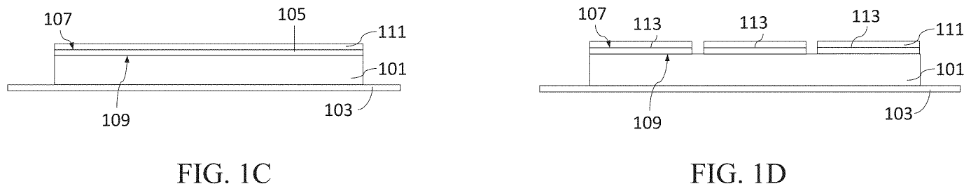

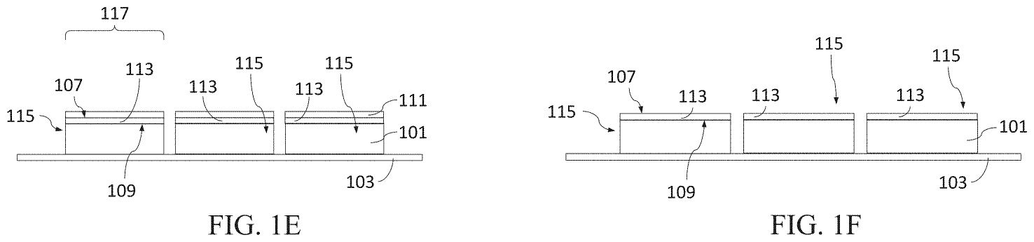

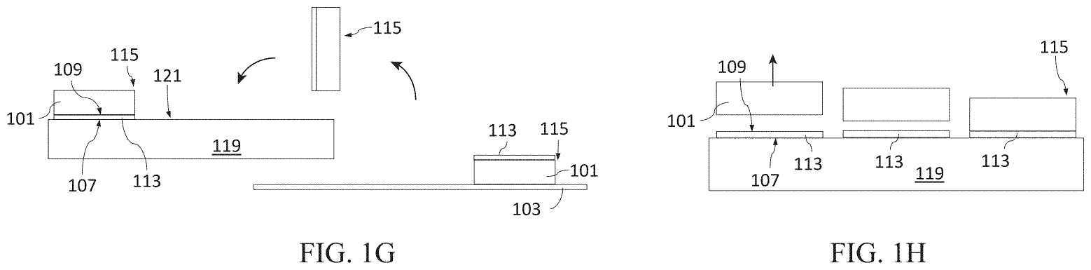

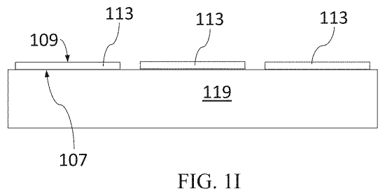

FIGS. 1A-1I depict a flow diagram of a first method of attaching thin dies to a substrate, according to embodiments of the present technology. FIG. 1A illustrates a support layer 101 mounted to a dicing structure, such as a dicing tape 103 (alternatively, a grip ring, or any other structure suitable for supporting a substrate during singulating) is provided. As an example, dicing tape 103 is a form of backing tape used to support a wafer during wafer dicing or singulation. The tape is configured to hold the diced substrate pieces (e.g., the diced integrated device dies) in place such that the dies remain attached to a dicing frame after dicing. After dicing, the dies can be selectively removed from the dicing tape 103. Dicing tape 103 is typically made from a backing material and an adhesive. The backing material is typically made from a thin layer of plastic. For example, in some embodiments, the backing material is made from PVC, polyolefin, or polyethylene. In some embodiments, the backing material may have a thickness between 80 and 120 microns. The adhesive used can be based on the specific wafer and substrate designs, sizes, and materials. In some embodiments, the adhesive layer may have a thickness between 5 and 15 microns. In some embodiments, the adhesive may be configured to cross link and lose adhesion after being exposed to ultraviolet (UV) or microwave radiation (or both UV and microwave radiation). In these embodiments, the dicing tape 103 is configured to strongly hold the wafer in place during dicing. After dicing the wafer into individual dies, the dicing tape 103 may be exposed, for example, to ultraviolet radiation, which reduces the adhesion of the adhesive and weakens the strength of the adhesive bond between the dicing tape 103 and the dies. This allows the dies to be more easily detached from the tape. In other embodiments, the dicing tape 103 can comprise thermal release tape having an adhesive configured to lose adhesion after being heated above a given temperature.

The support layer 101 can be configured to support a thin wafer during the dicing process performed to singulate the wafer into a plurality of thinned dies. Thinned dies, which may have a thickness of less than 100 microns, less than 50 microns, less than 30 microns, or less than 20 microns, are typically delicate such that mechanically handling the dies during bonding may introduce cracks and other defects to the thin dies. The thin dies may also be prone to deformation and warping when picked up using a pick-and-place tool. In general, the support layer 101 can be made from a material capable of absorbing forces imparted on the wafers and dies during processing so as to prevent the wafers and dies from cracking, breaking, or chipping. In some embodiments the support layer 101 can be formed from a flexible material capable of deforming when stressed but that has enough rigidity to support the thin die during processing. In another embodiment, the support layer 101 comprises an ultraviolet (UV) release polymer sheet or a thermal release polymer sheet. In another embodiment, the support layer 101 comprises a porous support layer.

In one embodiment, the support layer 101 comprises a porous material such as a porous polymeric material. The porous material may be an open cell or closed cell material, and in some embodiments, a closed cell foam may be preferable to prevent the incorporation of cleaning fluids within the pores of the porous polymeric material. In other embodiments, the support layer 101 may be a combination of a closed cell polymeric material and open cell polymeric foam. In various embodiments, the closed cell material may be formed around the open cell foam. The support layer 101 may absorb 10% to 97% of the impact force exerted by the bonding tool during the die or wafer bonding operation. The support layer 101 can comprise a non-rigid material. In some embodiments, the support layer 101 may comprise, for example, styrene polymers, styrene copolymers and/or their various blends, polystyrene foam, expanded polystyrene foam and their various analogues, an elastomeric material, and other suitable polymers. The elastomeric material for example may comprise of for example rubber, styrene-butadiene rubber (SBR), polyurethane foam, polyethylene foam or polyolefin foam. The apparent density of the support layer 101 may be in a range of 20 kg/m³ to 200 kg/m³, for example, in a range of 30 kg/m³ to 180 kg/m³. Similarly, the 25% Compression Hardness of the support layer 101 may be in a range of 0.01 MPa to 0.4 MPa, e.g., less than 0.37 MPa. The elongation of the support layer 101 material may vary between 10% to 300%, for example, less than 260%. The tensile strength of the support layer 101 material may be in a range of 1.5 kPa to 600 kPa, e.g., in a range of 3 kPa to 350 kPa. The Young's Modulus of the support layer 101 may be in a range of 0.04 GPa to 8 GPa, e.g., in a range of 0.5 GPa to 5 GPa, or in a range of 1 GPa to 5 GPa. In some embodiments, the glass transition temperature of the support layer 101 is less than 250° C., less than 200° C. and less than 150° C. or 120° C.

Regardless of the type of the material of the support layer 101, the support layer 101 may comprise an antistatic material which does not transmit the cleaning chemicals or contaminate the die or dies during the various chemicals cleaning operation for die bonding operation. In some embodiments, the support layer 101 may have a thickness between about 10 microns and 400 microns. In some embodiments, the support layer 101 may be devoid of active circuitry (e.g., devoid of transistors).

In various embodiments, the support layer 101 can comprise a thin sheet (or film or tape) of a PVCm polyolefin or polyethylene backing material with an adhesive layer on one side to form a bond with the thin die. The tape can be designed to reduce adhesion when exposed to external stimulation such as UV exposure or heat. One example of such a support material is the REVALPHA™ thermal release sheet for electronic component processing from Nitto Denko Corporation of Osaka, Japan. Another example of the support layer 101 is a UV release dicing tapes that can be used for wafer dicing. A combination of dicing tapes with a different release mechanisms as a support layer 101 and a dicing tape 103 can simplify the die release before bonding and removal of the support layer 101 after bonding. For example, a heat release tape can be used as a support layer 101 and a UV release tape can be used for dicing, or vice versa.

FIG. 1B illustrates a thin wafer 105 is attached to the support layer 101. The thin wafer 105 has a bonding surface 107 and a back surface 109, and the thin wafer 105 is attached to the support layer 101 such that the back surface 109 (which may also be referred to as the backside) is in contact with the support layer 101. In some embodiments, active circuitry (e.g., one or more transistors) can be provided in the wafer at or near the bonding surface 107, e.g., closer to the bonding surface 107 than to the back surface 109. The thin wafer 105 may be attached to the support layer 101 in any suitable manner. For example, the wafer 105 can be thinned before attaching the thin wafer 105 to the support layer 101. In some embodiments, the thin wafer 105 and the support layer 101 may be attached together with an adhesive. The adhesive is configured to securely hold the thin wafer 105 to the support layer 101 so that the support layer 101 can provide support to the thin wafer 105 during the dicing process. In some embodiments, the adhesive is a UV adhesive that is configured to cross link and lose adhesion after being exposed to UV radiation.

In other embodiments, the adhesive may be a thermal release adhesive that is configured to reduce adhesion after being exposed to thermal radiation. In still other embodiments, adhesion can be reduced in response to a different external stimulus such as microwave radiation. In other embodiments, however, the thin wafer 105 may be attached to the support layer 101 without using an adhesive. Instead, the thin wafer 105 may be directly bonded to support layer 101. For example, in embodiments where the thin wafer 105 and the support layer 101 each comprise portions of non-conductive material, the thin wafer 105 and the support layer 101 can be directly bonded together using various bonding techniques, including direct dielectric bonding, non-adhesive bonding techniques (e.g., ZiBond®), or hybrid bonding techniques (e.g., DBI®). In some embodiments, forming the bonding surface 107 comprises activating the bonding surface 107. For example, activating the bonding surface 107 comprises exposing the bonding surface 107 to a nitrogen-containing plasma. In various embodiments, the support layer 101 can be thicker than the wafer (or die). The thickness of the thinned wafer (or die) can be less than 50 microns, or less than 30 microns. In some embodiments, one or more additional wafers (e.g., thinned wafers) can be directly bonded to the thin wafer 105 without adhesive.

FIG. 1C illustrates a protective layer 111 is deposited on the thin wafer 105 such that it coats the bonding surface 107 of the thin wafer 105. The protective layer 111 is configured to protect the bonding surface during singulation. For example, during singulation, debris is created which may contaminate the bonding surface. The protective layer 111 can be provided to prevent debris from contaminating the bonding surface 107. In some embodiments, providing the protective layer 111 comprises providing an organic layer, e.g., a resist layer. In other embodiments, the protective layer 111 comprises an organic layer, e.g., a resist layer. Before the protective layer 111 is deposited onto the wafer, the bonding surface 107 of the thin wafer 105 can be prepared for direct bonding. For example, the wafer can be polished or planarized, e.g., with a chemical mechanical polishing (CMP) process to form a planarized bonding surface. In some embodiments, the bonding surface 107 can be activated before the protective layer 111 is applied. For example, the bonding surface 107 can be activated with a plasma, such as a nitrogen-containing plasma.

FIG. 1D illustrates the wafer and protective layer 111 can be singulated to form individual thin dies 113. In some embodiments, the wafer can be singulated using reactive-ion etching. However, this is merely an example and singulation can be performed using any other suitable means. For example, in other embodiments, the wafer can be singulated using a saw. The protective layer 111 is configured to protect the bonding surface 107 of the thin wafer 105 during the singulation process. In the embodiment, the singulation step can be performed to singulate only the thin wafer 105 without singulating the support layer 101. In other embodiments, a singulation step can be performed to singulate the thin wafer 105 and the support layer 101.

FIG. 1E illustrates the support layer 101 is also singulated to form a plurality of support layer sections 115. Each of the support layer sections 115 can be stacked together with one of the thin dies 113 to form a plurality of semiconductor die components 117. For each of the semiconductor die components 117, the support layer sections 115 can be configured to fully support the corresponding thin die. In some embodiments, singulating the support layer 101 comprises singulating the support layer 101 without singulating the dicing tape 103 such that, after singulating the support layer 101, the semiconductor die components 117 remain attached to the dicing tape 103. Thus, in Step 5, the support layer 101 can be singulated after singulating the wafer. In some embodiments, singulating the thin wafer 105, the protective layer 111, and the support layer 101 to form the semiconductor die components 117 imparts mechanical stress into the thin die. In this manner, the non-rigid material of the support layer 101 can be configured to absorb at least some of the imparted mechanical stress.

FIG. 1F illustrates the protective layer 111 is removed from the thin dies 113 to prepare the bonding surface 107 of the corresponding thin die. The protective layer 111 can be removed from the thin dies 113 in any suitable manner. For example, in some embodiments, the protective layer 111 can be removed in an ashing process, for example, by exposing the protective layer 111 to an oxygen plasma. In other embodiments, the protective layer 111 can be washed off with a liquid chemical, etched off or can be scraped off. The removal of the protective layer 111 can expose the bonding surface 107 of the thin dies 113, which may be ready for direct bonding (since the bonding surface 107 may be prepared for bonding before providing the protective layer 111). In other embodiments, the bonding surface 107 may be alternatively or additionally polished after removal of the protective layer 111 to ensure that the bonding surface 107 is ready for bonding.

FIG. 1G illustrates the semiconductor die components 117 are removed from the dicing tape 103 and attached to a substrate 119 such that the bonding surface 107 of the thin die 113 is in contact with, and directly bonded to, a top surface 121 of the substrate 119 without an intervening adhesive. In some embodiments, a pick-and-place tool may be used to remove the semiconductor die components 117 from the dicing structure (such as a dicing tape 103). The pick-and-place tool may include a vacuum pick-up tool configured to use suction to pick up and manipulate the semiconductor die components 117. When picking up the semiconductor die components 117, the pick-and-place tool may be positioned such that the tool is in contact with the bonding surface 107 of the thin die 113. The tool may then apply a suction force to the bonding surface 107 to cause the semiconductor die component to detach from the dicing tape. The support layer sections 115 may be configured to absorb some of the stress imparted on the thin die 113 by the tool so as to prevent the thin die 113 from cracking or warping due to the forces applied to the thin die 113 during the pick-up process. In some embodiments, attaching the semiconductor die components 117 to the substrate 119 comprises attaching the semiconductor die components 117 to the substrate 119 without touching the back surface 109.

In some embodiments, before the pick-and-place tool is used to detach the semiconductor die components 117 from the dicing structure, the dicing structure may be treated to reduce the adhesion between the support layer sections 115 and the dicing structure. For example, in embodiments where the dicing structure comprises UV tape, the dicing structure (e.g., dicing tape) may be exposed to UV radiation before the pick-and-place tool is used to detach the semiconductor die components 117 from the dicing structure. Similarly, in embodiments where the dicing structure comprises thermal release tape, the dicing structure may be heated prior to the pick-and-place tool being used to detach the semiconductor die component from the dicing structure. However, in other embodiments, the pick-and-place tool may be used to detach the semiconductor die component from the dicing structure without performing any additional treatment on the dicing structure.

After detaching the semiconductor die components 117 from the dicing structure, the pick-and-place tool moves semiconductor die components 117 over the substrate 119 and rotates or flips the components such that the bonding surface 107 of the thin die 113 is facing the substrate 119. The pick-and-place tool can place the semiconductor die component on the substrate 119 such that the bonding surface 107 is in direct contact with a top surface 121 of the substrate 119 and the thin die 113 is positioned between the support layer 101 and the substrate 119. After placing the semiconductor die components 117 on the substrate 119, the thin die 113 and the substrate 119 can be bonded together. In some embodiments, the thin die 113 and the substrate 119 can be directly bonded together without using an adhesive. For example, in some embodiments, the thin die 113 and the substrate 119 can be directly bonded together using various bonding techniques, including direct nonconductive (e.g., dielectric) bonding or other non-adhesive bonding techniques (e.g., ZiBond®). For example, in some embodiments the thin dies 113 and the substrate 119 may each comprise a non-conductive material, such as a dielectric (e.g., silicon oxide, silicon nitride, silicon oxynitrocarbide, etc.). In these embodiments, the thin die 113 and the substrate 119 can be bonded together using dielectric-to-dielectric bonding techniques to form covalent bonds. In other embodiments, the thin die 113 and substrate 119 can be bonding using hybrid bonding techniques in which dielectric and conductive regions are directly bonded to corresponding dielectric and conductive regions of the substrate 119.

The substrate 119 can comprise any suitable type of carrier for the thinned die. For example, in some embodiments, the substrate 119 can comprise a wafer, e.g., an active device wafer or a dummy or handle wafer. In other embodiments, the substrate 119 can comprise another integrated device die, an interposer, a packaging substrate, or any other suitable carrier. In some embodiments, the substrate 119 can have one or more conductive contact pads on the top surface 121 of the substrate 119 and the thin die 113 can have one or more conductive contact pads on the bonding surface 107. In these embodiments, the pick-and-place tool may be configured to place the semiconductor die component on the substrate 119 such that the conductive contact pads on the bonding surface 107 of the thin die 113 are aligned with the conductive contact pads on the top surface 121 of the substrate 119. The thin dies 113 and the substrate 119 can be directly bonded together without an adhesive. In some embodiments, the thin dies 113 and the substrate 119 can be directly bonded together using hybrid bonding techniques (e.g., DBI®). In these embodiments, the conductive contact pads on the thin dies 113 and on the substrate 119 can be bonded together with conductor-to-conductor direct bonds while non-conducting portions of the bonding surface 107 can be covalently bonded to non-conducting portions of the top surface 121 of the substrate 119. In some embodiments, the thin die 113 may comprise a large thin unsingulated wafer to be bonded to another substrate.

FIG. 1H illustrates after bonding the thin dies 113 to the substrate 119, the support layer sections 115 can be removed from the thin dies 113, thereby exposing the back surface 109 of the thin dies 113. In some embodiments, the support layer sections 115 can be stripped from the thin dies 113 by first exposing the support layer 101 to UV radiation, which weakens the bond between the thin dies 113 and the support layer sections 115. The support layer sections 115 can then be detached from the back surface 109 of the thin dies 113. In another embodiment, heating can be used to weaken the adhesion between the die and the support layer 101 to facilitate removal. In some embodiments, the pick-and-place tool can be used to detach the support layer sections 115 from the thin dies 113. However, this is only an example. In other embodiments, a different tool may be used to strip the support layer sections 115 from the thin dies 113. In still other embodiments, the support layer sections 115 may be stripped from the thin dies 113 without exposing the support layer 101 to UV radiation and may instead be stripped using only the pick-up tool or some other tool.

FIG. 1I illustrates after stripping the support layer sections 115 from the thin dies 113, the thin dies 113 remain bonded to the substrate 119. In some embodiments, the substrate 119 can comprise a temporary handle or carrier wafer, and the dies 113 can be subsequently removed. In other embodiments, the substrate 119 can comprise a device wafer or substrate and the dies 113 can remain bonded to the substrate 119.

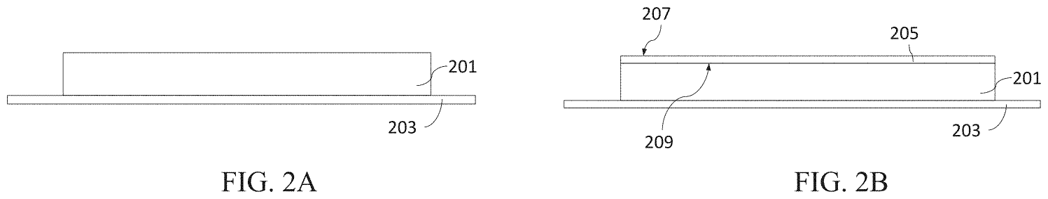

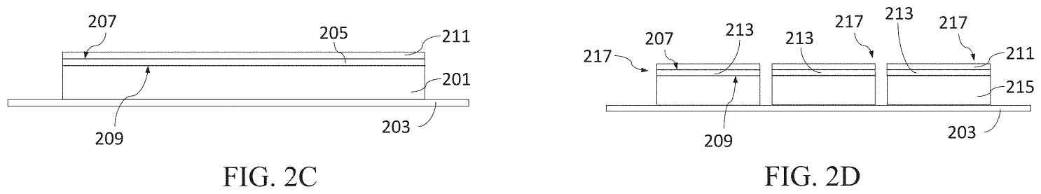

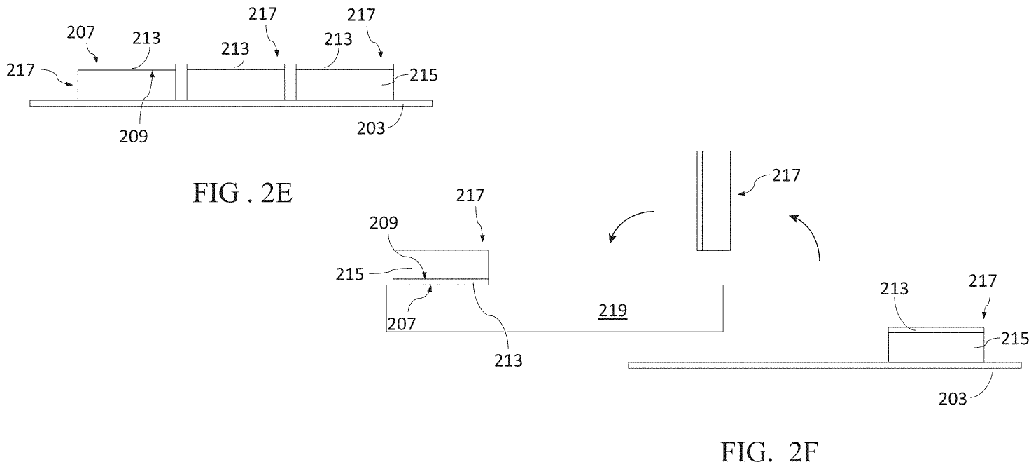

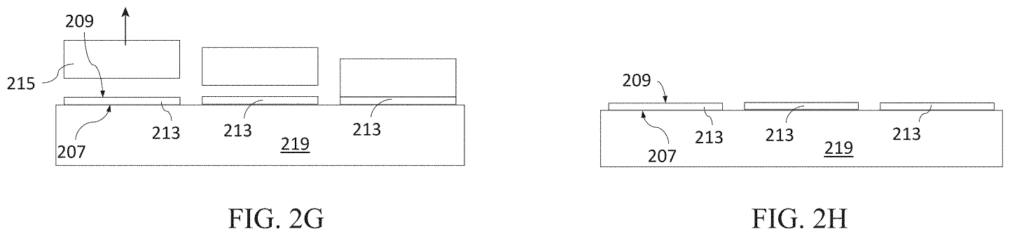

FIGS. 2A-2H depict a flow diagram of a second method of attaching thin dies to a substrate. As described above in connection with FIGS. 1A-1I, FIG. 2A illustrates a support layer 201 is mounted to a dicing tape 203. FIG. 2B illustrates a thin wafer 205 is attached to the support layer 201. As noted above, in some embodiments, one or more additional wafers can be bonded to the wafer 205. FIG. 2C illustrates a protective layer 211 is deposited or attached to a bonding surface 207 of the thin wafer 205. The thin wafer 205 is attached to the support layer 201 such that a back surface 209 (which may also be referred to as the backside) is in contact with the support layer 201. FIG. 2D illustrates instead of singulating the thin wafer 205 and the support layer 201 in separate steps, the thin wafer 205 and support layer 201 are singulated in a single step to form semiconductor die components 217 of thin dies 213 and support layer sections 215. In some embodiments the wafer and support layer 201 can be singulated using reactive-ion etching. However, this is merely an example and singulation can be performed using any other suitable means. For example, in other embodiments, the wafer and support layer 201 can be singulated using a saw. FIG. 2E illustrates the protective layer 211 is removed from the thin dies 213 to prepare the bonding surface 207 of the dies. FIG. 2F illustrates the semiconductor die components 217 are removed from the dicing tape 203 and are attached to a substrate 219 such that the bonding surface 207 of the thin dies 213 is in contact with the top surface the substrate 219. FIG. 2G illustrates the support layer sections 215 are stripped from the thin dies 213. FIG. 2H illustrates the thin dies 213 remain bonded to the substrate 219.

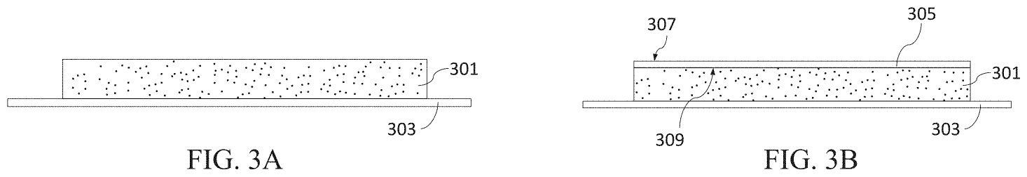

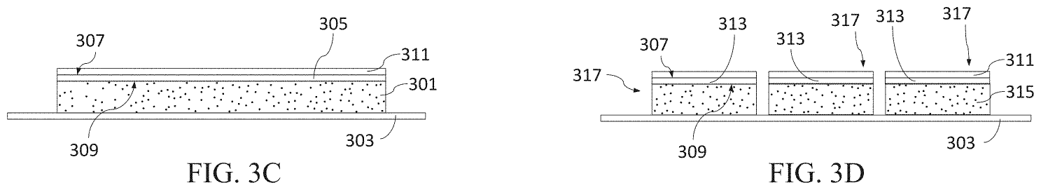

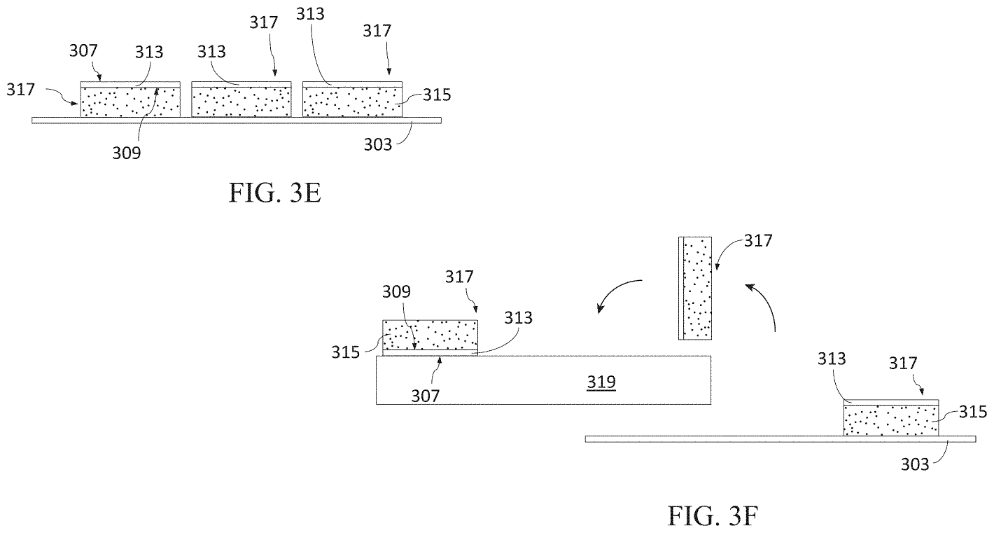

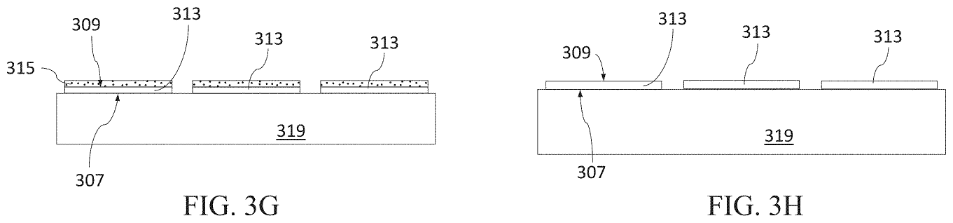

FIGS. 3A-3H depict a flow diagram of a third method of attaching thin dies to a substrate using a porous support layer. FIG. 3A illustrates a porous support layer 301 is mounted to dicing tape 303. FIG. 3B illustrates a thin wafer 305 is attached to the support layer 301. FIG. 3C illustrates a protective layer 311 is attached to the bonding surface 307 of the thin wafer 305. The thin wafer 305 is attached to the porous support layer 301 such that a back surface 309 (which may also be referred to as the backside) is in contact with the porous support layer 301. FIG. 3D illustrates the thin wafer 305, porous support layer 301, and protective layer 311 are singulated to form semiconductor die components 317 of thin dies 313 and porous support layer sections 315. FIG. 3E illustrates the protective layer 311 is removed from the thin dies 313 to prepare the bonding surface 307 for the dies. FIG. 3F illustrates the semiconductor die components 317 are removed from the dicing tape 303 and coupled to a substrate 319 such that the bonding surface 307 of the thin die 313 is directly bonded to top surface of the substrate 319. FIG. 3G illustrates the porous support layer sections 315 are removed from the thin die 313 using etching. The porous support layer 301 can be made from a porous material that can be etched away or removed with an organic solvent. One example of a porous material includes porous plastic sheets with open pores sold by Porex Corporation of Fairburn, Ga. A non-UV curable adhesive can be used to fix the die to the porous sheet. After bonding, the adhesive layer can be dissolved with a solvent such as acetone to release the support layer.

In some embodiments, the porous support layer 301 can comprise a styrene based material or foam, in which case the support layer is readily dissolved in a suitable ketone, for example, acetone, methyl ethyl ketone (MEK) or in aliphatic hydrocarbons, carbon disulfide, chloroform, cyclohexanone, ethyl acetate, NMP, THF and others. A polyurethane support layer may be stripped with a dimethyl sulfoxide (DMSO), tetrahydrofuran (THF), N-methyl-2-pyrrolidone (NMP), or Stoner's B510 Light Duty Cleaner. The support layer stripping chemicals and process may not degrade the bonding surface (e.g., corrode or etch the conductive pad layer recess substantially). In addition to chemical stripping, laser ablation may be used to strip the support layer from a backside of the bonded die or dies. Post-ablation cleaning may be needed with suitable solvents to clean particulates and any undesirable material residues off the bonding surface of the substrate 319 and the backside of the bonded die. FIG. 3H illustrates after etching the porous support layer sections 315 away, the thin dies 313 remain bonded to the substrate 319.

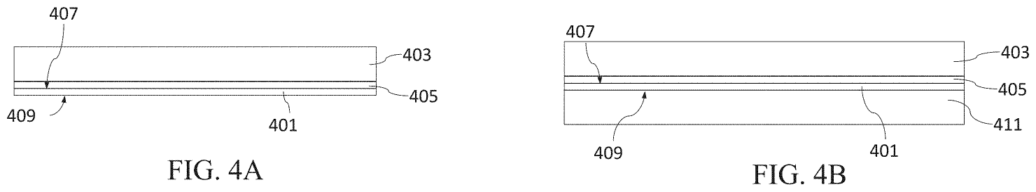

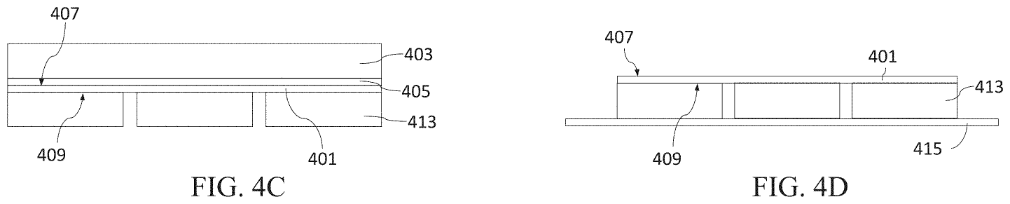

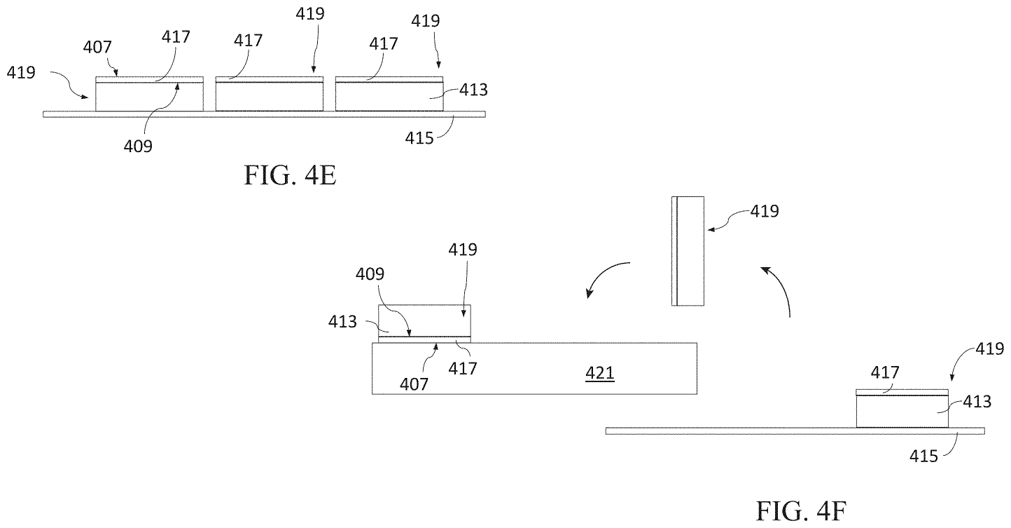

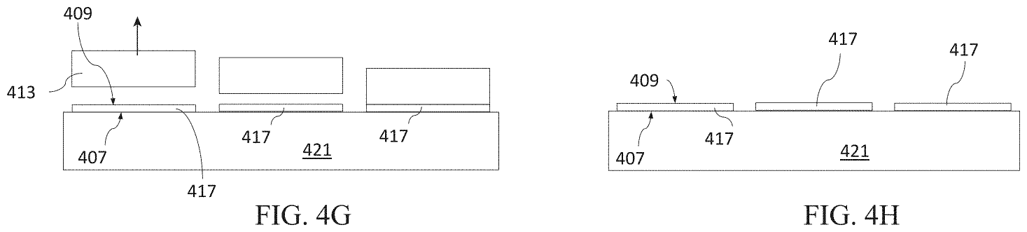

FIGS. 4A-4H depict a flow diagram of a method of attaching thin dies to a substrate using a support layer. The wafer can be thinned by attaching a thicker active wafer to a handle wafer (also referred to herein as a handle). The backside of the thicker wafer can be grinded or polished to form the thin wafer shown in FIGS. 4A-4H. Thus, FIG. 4A illustrates a thin wafer 401 attached to a handle 403 is provided. The handle 403 is configured to provide structural support to the thin wafer 401 during processing so that the thin wafer 401 does not break or deform during processing of the wafer. The handle 403 may be formed from a suitably durable material such that the handle 403 can survive stresses caused by temperature variations during processing, grinding the thin wafer 401, or other stresses. In some embodiments, the handle 403 may be formed from a material that is more rigid than the thin wafer 401, such as a thicker silicon wafer or glass.

To ensure that the handle 403 can provide sufficient support to the thin wafer 401 during processing, the wafer can be securely attached to the handle 403. In the illustrated embodiment, a layer of adhesive 405 is used to attach the handle 403 to the carrier. The adhesive 405 may be configured to securely attach the thin wafer 401 to the handle 403 so that the thin wafer 401 does not deform or break during processing. However, securing the wafer to the handle 403 using an adhesive 405 is merely illustrative. In other embodiments, the handle 403 is directly bonded to the thin wafer 401. More specifically, the thin wafer 401 may be bonded to the handle 403 such that a bonding surface 407 of the thin wafer 401 is in direct contact with a surface of the handle 403 and covalent bonds are formed between non-conductive portions of the thin wafer 401 and the handle 403. The thin wafer 401 is attached to the adhesive 405 such that a back surface 409 (which may also be referred to as the backside) is disposed on a surface opposite the adhesive 405.

FIG. 4B illustrates a support layer 411 is attached to the thin wafer 401. The support layer 411 is attached to the back surface 409 of the thin wafer 401 such that the handle 403 and the support layer 411 are on opposing sides of the thin wafer 401. In some embodiments, the support layer 411 is attached to the thin wafer 401 by directly bonding the support layer 411 to the back surface 409 of the thin wafer 401. In some embodiments, attaching the support layer 411 to the thin wafer 401 includes keeping the support layer 411 stationary while moving the thin wafer 401 using the handle 403. In these embodiments, the handle 403 is used to move the thin wafer 401 until the back surface 409 contacts the support layer 411. In other embodiments, attaching the support layer 411 to the thin wafer 401 includes keeping the thin wafer 401 stationary while moving the support layer 411 until the back surface of the support layer 411 contacts the thin wafer 401. In still other embodiments, attaching the support layer 411 to the thin wafer 401 includes moving both the thin wafer 401 and the support layer 411 until the back surface 409 of the thin wafer 401 contacts the support layer 411.

FIG. 4C illustrates the support layer 411 is singulated into support layer sections 413. The support layer 411 may be singulated using reactive-ion etching, a saw, or any other suitable means. The support layer 411 may be singulated without singulating the thin wafer 401 or the handle 403.

FIG. 4D illustrates a dicing structure, such as dicing tape 415 (e.g., a grip ring, or any other structure suitable for supporting a substrate during singulating) is attached to the support layer 411 and the handle 403 is detached from the thin wafer 401. In some embodiments, the dicing tape 415 is attached to the support layer 411 before the handle 403 is detached from the thin wafer 401. In embodiments where the handle 403 is attached to the thin wafer 401 with a layer of adhesive 405, the adhesive 405 may be configured to lose adhesion after being exposed to an external stimulus. Accordingly, detaching the handle 403 from the thin wafer 401 may include exposing the handle 403 and/or the adhesive 405 to the external stimulus. For example, in some embodiments, the adhesive 405 may be a UV adhesive configured to break down after being exposed to UV radiation. In these embodiments, detaching the handle 403 from the thin wafer 401 may include exposing the handle 403 and/or the adhesive 405 to UV radiation. In other embodiments, the adhesive 405 may be a thermal release adhesive configured to lose adhesion after being heated above a given temperature and detaching the handle 403 from the thin wafer 401 may include heating the handle 403 and/or the adhesive 405. In still other embodiments, the adhesive 405 may lose adhesion in response to a different external stimulus. In still other embodiments, the handle 403 may be removed from the thin wafer 401 without applying an external stimulus to the adhesive 405. Instead, the handle 403 may be removed from the thin wafer 401 using entirely mechanical processes such as grinding the handle 403 or a chemical process such as etching it. In these embodiments, the handle 403 may be considered a sacrificial handle. In embodiments where the thin wafer 401 is directly bonded to the handle 403, the handle 403 may be removed from the thin wafer 401 by grinding the handle 403 down.

After removing the handle 403 from the thin wafer 401, some pieces of the handle 403 and/or the adhesive 405 may remain adhered to the bonding surface 407 of the thin wafer 401. To ensure that the bonding surface 407 is clean and ready for bonding, in some embodiments, the bonding surface 407 of the thin wafer 401 may be polished to remove any residue. The process of removing the handle 403 from the thin wafer 401 can impart stress into the thin wafer 401. To ensure that the thin wafer 401 does not deform or break during the removal process due to the imparted stress, the support layer sections 413 may be configured to absorb at least some of the stress from the thin wafer 401 so as to prevent the thin dies from breaking or deforming during the process.

FIG. 4E illustrates the thin wafer 401 is singulated into a plurality of thin dies 417. Each of the thin dies 417 may be supported by one of the support layer sections 413. The support layer sections 413 and the thin dies 417 may be stacked together to form semiconductor die components 419. In some embodiments, before singulating the thin wafer 401 into thin dies 417, a protective layer may be applied to the bonding surface 407 of the thin wafer 401. The protective layer may be configured to protect the bonding surface 407 of the thin die during the singulation process. After singulating the thin wafer 401, the protective layer may be removed. In some embodiments, the bonding surface 407 may also be polished to remove any residual resist material.

FIG. 4F illustrates the semiconductor die components 419 are removed from the dicing tape 415 and directly bonded to a substrate 421 such that the bonding surface 407 of the thin dies 417 is in contact with the top surface the substrate 421. FIG. 4G illustrates the support layer sections 413 are stripped from the thin dies 417, FIG. 4H illustrates the thin dies 417 remain bonded to the substrate 421.

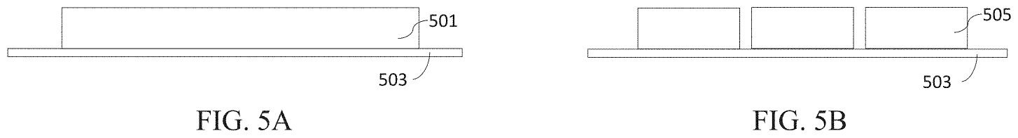

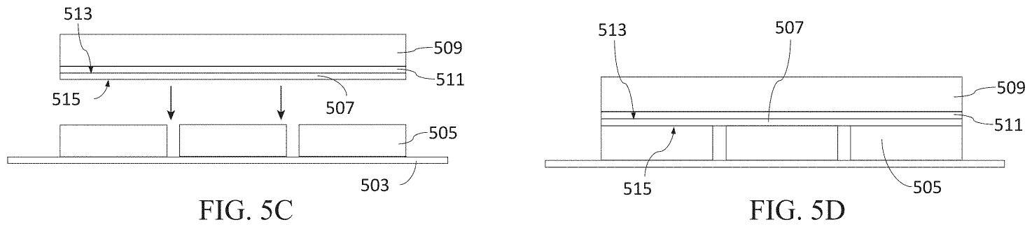

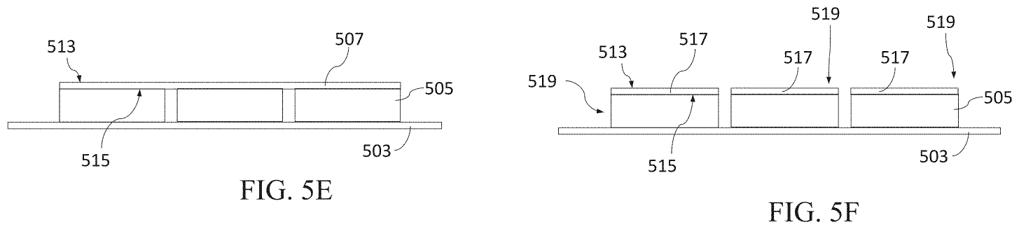

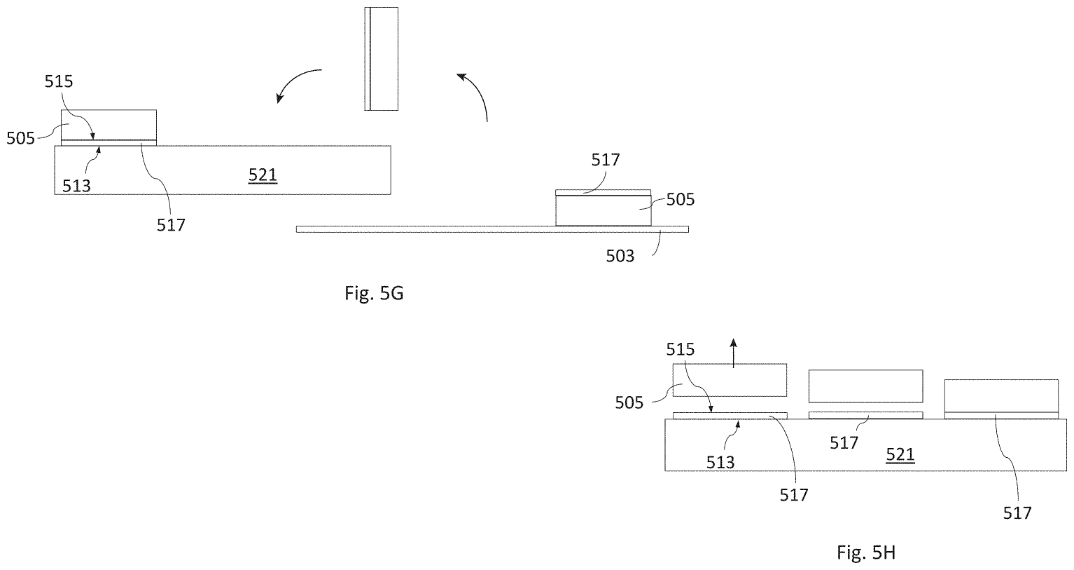

FIGS. 5A-5I depict a flow diagram of an alternative method of attaching thin dies to a substrate using a handle and a support layer. FIG. 5A illustrates a support layer 501 attached to dicing tape 503 is provided. FIG. 5B illustrates the support layer 501 is singulated into a plurality of support layer sections 505. FIG. 5C illustrates a thin wafer 507 attached to a handle 509 is provided and is positioned over the support layer sections 505 of the support layer 501. In the illustrated embodiment, the thin wafer 507 is attached to the handle 509 with an adhesive 511. In other embodiments, however, the thin wafer 507 may be attached to the handle 509 without using the adhesive 511. For example, in some embodiments, the thin wafer 507 may be directly bonded to the handle 509. FIG. 5D illustrates the support layer sections 505 can be attached to the thin wafer 507. In some embodiments the support layer sections 505 are directly bonded to a back surface 515 of the thin wafer 507. In some embodiments, the thin wafer 507 and handle 509 may be aligned with the tape and the support layer sections 505 to ensure that the thin wafer 507 and the support layer sections 505 are properly aligned. FIG. 5E illustrates the handle 509 is detached from the thin wafer 507. In some embodiments, after removing the handle 509 from the thin wafer 507, a bonding surface 513 of the thin wafer 507 may be polished to remove any residue remaining on the bonding surface 513.

FIG. 5F illustrates the thin wafer 507 is singulated into a plurality of thin dies 517. Each of the thin dies 517 may be supported by one of the support layer sections 505. The support layer sections 505 and the thin dies 517 may be stacked together to form semiconductor die components 519. In some embodiments, before singulating the thin wafer 507 into thin dies 517, a protective layer may be applied to the bonding surface 513 of the thin wafer 507. The protective layer may be configured to protect the bonding surface 513 of the thin die during the singulation process. After singulating the thin wafer 507, the protective layer may be removed. In some embodiments, the bonding surface 513 may also be polished to remove any residual material from the bonding surface 513.

FIG. 5G illustrates the semiconductor die components 519 are removed from the dicing tape 503 and directly bonded to a substrate 521 such that the bonding surface 513 of the thin dies 517 is in contact with the top surface the substrate 521. For example, before directly bonding the semiconductor die components 519, removing a first semiconductor die component from the dicing tape 503 and flipping the first semiconductor die component such that the bonding surface 513 faces the substrate 521. FIG. 5H illustrates the support layer sections 505 are stripped from the thin dies 517. FIG. 5I illustrates the thin dies 517 remain bonded to the substrate 521.

Although only FIGS. 4A-4H and 5A-5I show using a handle to attach the thin wafer to the support layer, it should be understood the use of a handle to attach the thin wafer to the support layer should not be limited to the methods shown in FIGS. 4 and 5 but that a handle can be used in any of the previously described methods. For example, a handle can be used in the method shown in FIGS. 1A-1I, 2A-2H, or 3A-3H to attach the thin wafer to the support layer.

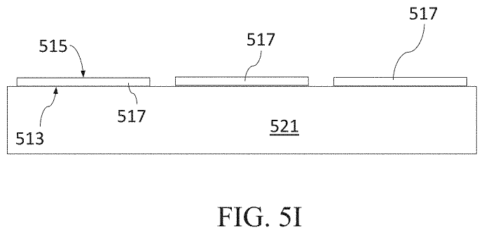

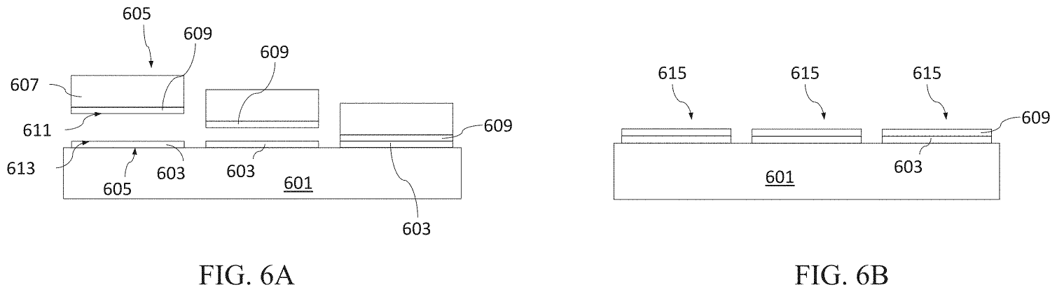

In the previously illustrated embodiments, the thin dies are bonded to the substrate such that each thin die is isolated from other dies. However, in other embodiments, multiple thin dies may be stacked together. Stacking multiple dies together allows for increased processing power and performance without increasing the footprint of the electronic device. FIGS. 6A-6C depicts a flow diagram for stacking multiple dies together on a substrate. FIG. 6A illustrates a substrate 601 having a plurality of thin dies 603 directly bonded to a surface of the substrate 601 is provided. In an embodiment, the thin dies 603 can be bonded to the substrate 601 using a bonding surface 613. A plurality of semiconductor die components 607 are positioned over the thin dies 603. Each of the semiconductor die components 607 comprises a support layer sections 609 and a thin die 611. The semiconductor die components 607 can be positioned such that the bonding surface 613 of the thin die 611 faces a back surface 615 of the thin die 603 bonded to the substrate 601. The semiconductor die components 607 are then coupled to the thin dies 603 on the substrate 601 such that the bonding surface 613 of the thin die 603 of the semiconductor die components 607 are directly bonded to the back surface 615 of the thin dies 603 on the substrate 601. In this way, two or more thin dies may be directly bonded to each other forming a die stack 617.

FIG. 6B illustrates the support layer sections 609 for each of the semiconductor die components 607 are removed from the bonded thin dies, thereby exposing a back surface of the thin die 603 of the semiconductor die components 607. FIG. 6C illustrates how the foregoing process can be repeated again to form stacks of three thin dies. For example, the die stack 617 can increase in the number of thin dies. The process can be repeated to form any suitable number of stacked dies. In some embodiments, the support layer sections 609 may comprise an electromagnetic wave absorption material, for example, a radio wave shielding material (e.g., a polyethylene foam AE-100, AE-200, AE-300 supplied by INOAC Corporation of Tokyo, Japan). In some embodiments, to perform its additional functions, the support layer sections 609 may be left intact over the back side of a bonded die (not shown).

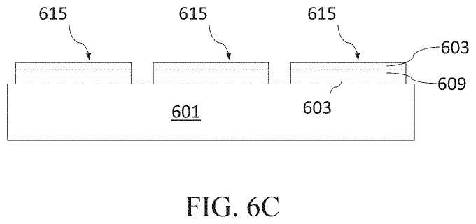

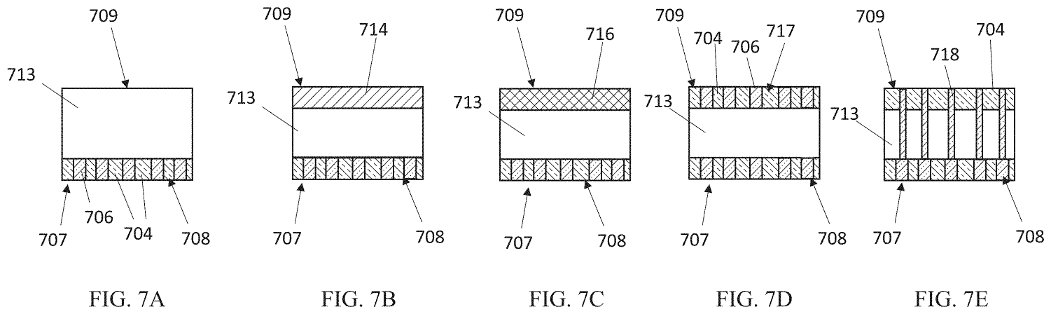

FIGS. 7A-7E illustrate example back side structures for thinned dies 713 configured to be mounted to any of the support layers described herein, according to various embodiments. As shown in FIG. 7A, the thinned dies 713 can have a front surface 707 (which may in various embodiments comprise a bonding surface prepared for direct bonding) and a back surface 709 opposite the front surface 707. In some embodiments, active circuitry (e.g., one or more transistors) may be provided at or near the front surface 707, e.g., closer to the front surface 707 than the back surface 709. A bonding layer 708 can at least partially define the front surface 707 and can comprise a nonconductive region 704 (e.g., an inorganic layer such as silicon oxide, etc.) and a plurality of conductive features 706 at least partially embedded in the nonconductive region 704. The die 713 can be thinned using any suitable planarization process (e.g., CMP) to form the thinned die 713 with the back surface 709 comprising markings indicative of the thinning process (e.g., scratches, scores, etc.). In some embodiments, the back surface 709 may be polished for form a very smooth surface.

The thin dies 713 can have various profiles defining the back surface 709. For example, as shown in FIG. 7B, a polymer layer 714 (e.g., PC43-6000, a planarizing coating supplied by Futurrex, Inc. located at 24F Munsonhurst Rd, Franklin, N.J. 07416) can be applied over the back side of the die 713 and partially etched back to form a planar back surface 709.

As shown in FIG. 7C, in some embodiments, a backside dielectric layer 716 can be provided over the back side of the die 713 to at least partially define the back surface 709. In various embodiments, the backside dielectric layer 716 can have a thickness and include a material configured to reduce or eliminate warpage of the thin die 713. The backside dielectric layer 716 can comprise an inorganic dielectric, such as silicon oxide, silicon nitride, silicon oxycarbonitride, etc., in various embodiments. In FIG. 7D, in some embodiments, the back surface 709 can comprise a back-end-of-line (BEOL) metallization layer 717 comprising a nonconductive layer 704 and a plurality of conductive regions 706. In various embodiments, the BEOL layer 717 can comprise vertical and/or lateral routing lines. In some embodiments, the BEOL layer 717 can define a backside bonding layer of the device. As shown in FIG. 7E, in some embodiments, the back surface 709 can comprise a nonconductive layer or region 704 with conductive through substrate vias (TSVs) extending through the die 713 and nonconductive region 704. In some embodiments, ends of the vias 718 can be exposed through the nonconductive region 704 by way of a planarization process. As explained above, an overall thickness of the die 713 (including, e.g., any front side and back side layers) can be less than 100 microns, less than 50 microns, less than 30 microns, or less than 20 microns.

### Examples of Direct Bonding Methods and Directly Bonded Structures

Various embodiments disclosed herein relate to directly bonded structures in which two elements can be directly bonded to one another without an intervening adhesive. Two or more semiconductor elements (such as integrated device dies, wafers, etc.) may be stacked on or bonded to one another to form a bonded structure. Conductive contact pads of one element may be electrically connected to corresponding conductive contact pads of another element. Any suitable number of elements can be stacked in the bonded structure.

In some embodiments, the elements are directly bonded to one another without an adhesive. In various embodiments, a non-conductive or dielectric material of a first element can be directly bonded to a corresponding non-conductive or dielectric field region of a second element without an adhesive. The non-conductive material can be referred to as a nonconductive bonding region or bonding layer of the first element. In some embodiments, the non-conductive material of the first element can be directly bonded to the corresponding non-conductive material of the second element using dielectric-to-dielectric bonding techniques. For example, dielectric-to-dielectric bonds may be formed without an adhesive using the direct bonding techniques disclosed at least in U.S. Pat. Nos. 9,564,414, 9,391,143, and 10,434,749, the entire contents of each of which are incorporated by reference herein in their entirety and for all purposes.

In various embodiments, hybrid direct bonds can be formed without an intervening adhesive. For example, dielectric bonding surfaces can be polished to a high degree of smoothness. The bonding surfaces can be cleaned and exposed to a plasma and/or etchants to activate the surfaces. In some embodiments, the surfaces can be terminated with a species after activation or during activation (e.g., during the plasma and/or etch processes). Without being limited by theory, in some embodiments, the activation process can be performed to break chemical bonds at the bonding surface, and the termination process can provide additional chemical species at the bonding surface that improves the bonding energy during direct bonding. In some embodiments, the activation and termination are provided in the same step, e.g., a plasma or wet etchant to activate and terminate the surfaces. In other embodiments, the bonding surface can be terminated in a separate treatment to provide the additional species for direct bonding. In various embodiments, the terminating species can comprise nitrogen. Further, in some embodiments, the bonding surfaces can be exposed to fluorine. For example, there may be one or multiple fluorine peaks near layer and/or bonding interfaces. Thus, in the directly bonded structures, the bonding interface between two dielectric materials can comprise a very smooth interface with higher nitrogen content and/or fluorine peaks at the bonding interface. Additional examples of activation and/or termination treatments may be found throughout U.S. Pat. Nos. 9,564,414, 9,391,143, and 10,434,749, the entire contents of each of which are incorporated by reference herein in their entirety and for all purposes.

In various embodiments, conductive contact pads of the first element can also be directly bonded to corresponding conductive contact pads of the second element. For example, a hybrid bonding technique can be used to provide conductor-to-conductor direct bonds along a bond interface that includes covalently direct bonded dielectric-to-dielectric surfaces, prepared as described above. In various embodiments, the conductor-to-conductor (e.g., contact pad to contact pad) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes.

For example, dielectric bonding surfaces can be prepared and directly bonded to one another without an intervening adhesive as explained above. Conductive contact pads (which may be surrounded by nonconductive dielectric field regions) may also directly bond to one another without an intervening adhesive. In some embodiments, the respective contact pads can be recessed below exterior (e.g., upper) surfaces of the dielectric or nonconductive bonding regions, for example, recessed by less than 30 nm, less than 20 nm, less than 15 nm, or less than 10 nm, for example, recessed in a range of 1 nm to 20 nm, or in a range of 4 nm to 10 nm. The nonconductive bonding regions can be directly bonded to one another without an adhesive at room temperature in some embodiments and, subsequently, the bonded structure can be annealed. Upon annealing, the contact pads can expand and contact one another to form a metal-to-metal direct bond. Beneficially, the use of hybrid bonding techniques, such as Direct Bond Interconnect, or DBI®, available commercially from Xperi of San Jose, Calif., can enable high density of pads connected across the direct bond interface (e.g., small or fine pitches for regular arrays). In some embodiments, the pitch of the bonding pads, or conductive traces embedded in the bonding surface of one of the bonded elements, may be less 40 microns or less than 10 microns or even less than 2 microns. For some applications the ratio of the pitch of the bonding pads to one of the dimensions of the bonding pad is less than 5, or less than 3 and sometimes desirably less than 2. In other applications the width of the conductive traces embedded in the bonding surface of one of the bonded elements may range between 0.3 to 3 microns. In various embodiments, the contact pads and/or traces can comprise copper, although other metals may be suitable.

Thus, in direct bonding processes, a first element can be directly bonded to a second element without an intervening adhesive. In some arrangements, the first element can comprise a singulated element, such as a singulated integrated device die. In other arrangements, the first element can comprise a carrier or substrate (e.g., a wafer) that includes a plurality (e.g., tens, hundreds, or more) of device regions that, when singulated, form a plurality of integrated device dies. Similarly, the second element can comprise a singulated element, such as a singulated integrated device die. In other arrangements, the second element can comprise a carrier or substrate (e.g., a wafer).

As explained herein, the first and second elements can be directly bonded to one another without an adhesive, which is different from a deposition process. In one application, a width of the first element in the bonded structure can be similar to a width of the second element. In some other embodiments, a width of the first element in the bonded structure can be different from a width of the second element. The width or area of the larger element in the bonded structure may be at least 10% larger than the width or area of the smaller element. The first and second elements can accordingly comprise non-deposited elements. Further, directly bonded structures, unlike deposited layers, can include a defect region along the bond interface in which nanovoids are present. The nanovoids may be formed due to activation of the bonding surfaces (e.g., exposure to a plasma). As explained above, the bond interface can include concentration of materials from the activation and/or last chemical treatment processes. For example, in embodiments that utilize a nitrogen plasma for activation, a nitrogen peak can be formed at the bond interface. In embodiments that utilize an oxygen plasma for activation, an oxygen peak can be formed at the bond interface. In some embodiments, the bond interface can comprise silicon oxynitride, silicon oxycarbonitride, or silicon carbonitride. As explained herein, the direct bond can comprise a covalent bond, which is stronger than van Der Waals bonds. The bonding layers can also comprise polished surfaces that are planarized to a high degree of smoothness.

In one embodiment, a method of forming a microelectronic assembly is disclosed. The method can include attaching a wafer to a support layer; singulating the wafer with the support layer attached to a dicing structure to form a plurality of semiconductor die components, each semiconductor die component of the plurality of semiconductor die components having a die and a support layer section of the support layer attached to the die, the support layer section disposed between the die and the dicing structure; and directly bonding a first semiconductor die component of the plurality of semiconductor die components to a substrate without an intervening adhesive, such that the die is disposed between the substrate and the support layer section.

In some embodiments, the method includes after the directly bonding, removing the support layer section from the die. In some embodiments, the method includes providing a second semiconductor die component having a second die and a second support layer section attached to the second die; and after the removing, directly bonding the second die to the die without an adhesive such that the second die is disposed between the die and the second support layer section. In some embodiments, the method includes after attaching the wafer to the support layer, attaching the support layer to the dicing structure. In some embodiments, the method includes before attaching the wafer to the support layer, attaching the support layer to the dicing structure. In some embodiments, the method includes singulating the wafer before singulating the support layer. In some embodiments, the method includes singulating the wafer and the support layer in a single dicing process. In some embodiments, the method includes dicing the support layer into a plurality of support layer sections before attaching the support layer to the dicing structure. In some embodiments, the method includes before the singulating, providing a protective layer over a bonding surface of the wafer. In some embodiments, attaching the wafer to the support layer comprises attaching a back surface of the wafer to the support layer, the back surface opposite the bonding surface. In some embodiments, the method includes before providing the protective layer, forming the bonding surface, forming the bonding surface comprising planarizing the wafer. In some embodiments, forming the bonding surface comprises activating the bonding surface. In some embodiments, activating the bonding surface comprises exposing the bonding surface to a nitrogen-containing plasma. In some embodiments, providing the protective layer comprises providing an organic layer. In some embodiments, the method includes before directly bonding, removing the first semiconductor die component from the dicing structure and flipping the first semiconductor die component such that a bonding surface of the die faces the substrate. In some embodiments, the method includes providing the support layer, the support layer comprising an ultraviolet (UV) release polymer sheet or a thermal release polymer sheet. In some embodiments, the method includes providing the support layer, the support layer comprising a porous support layer. In some embodiments, the method includes thinning the wafer before attaching the wafer to the support layer. In some embodiments, attaching the wafer to the support layer comprises attaching the wafer to the support layer with an adhesive. In some embodiments, the adhesive comprises an ultraviolet (UV) adhesive configured to lose adhesion after being exposed to UV radiation, the method comprising detaching the support layer section from the die by exposing the adhesive to UV radiation. In some embodiments, the method includes providing the support layer, the support layer devoid of active circuitry.

In another embodiment, a method of forming a microelectronic assembly is disclosed. The method can include: attaching a support layer to a dicing structure; attaching a wafer to the support layer; providing a protective layer on the wafer; singulating the wafer, the protective layer, and the support layer to form a semiconductor die component having a thinned die and a support layer section stacked together; removing the protective layer from the semiconductor die component to expose a bonding surface of the thinned die; detaching the semiconductor die component from the dicing tape; attaching the semiconductor die component to a substrate such that the thinned die is interposed between the support layer section and the substrate and the bonding surface of the thin die is directly bonded to the substrate without an intervening adhesive; and after attaching the semiconductor die component to the substrate, detaching the support layer section from the thinned die to expose a back surface of the thinned die.

In some embodiments, singulating the wafer, the protective layer, and the support layer comprises forming a second semiconductor die component having a second thinned die and a second support layer section stacked together. In some embodiments, the method includes removing the protective layer from the second semiconductor die component to expose a bonding surface of the second thinned die; detaching the second semiconductor component from the dicing tape and attaching it to the substrate such that the second thinned die is interposed between the second support layer section and the substrate, and the bonding surface of the second thinned die is directly bonded to the substrate without an intervening adhesive; and detaching the second support layer section from the second thinned die to expose a back surface of the second thinned die. In some embodiments, the method includes providing a second semiconductor die component having a second thinned die and a second support layer section attached to the second thinned die; and directly bonding the second thinned die to the thinned die without an adhesive such that the second thinned die is disposed between the thinned die and the second support layer section. In some embodiments, the method includes removing the second support layer section from the second thinned die. In some embodiments, the method includes directly bonding a third die to the second thinned die without an intervening adhesive. In some embodiments, attaching the wafer to the support layer comprises attaching the wafer to the support layer with an adhesive. In some embodiments, the adhesive comprises a UV adhesive configured to break down after being exposed to UV radiation, and detaching the support layer section from the thin die comprises exposing the adhesive to UV radiation. In some embodiments, the support layer comprises a non-rigid material, singulating the wafer, the protective layer, and the support layer to form the semiconductor die component imparts mechanical stress into the thin die, and the non-rigid material is configured to absorb at least some of the imparted mechanical stress. In some embodiments, attaching the semiconductor die component to the substrate comprises attaching the semiconductor die component to the substrate without touching the back surface of the thinned die. In some embodiments, the method includes singulating the wafer before singulating the support layer. In some embodiments, the method includes singulating the wafer and the support layer in a single dicing process. In some embodiments, singulating the support layer comprises singulating the support layer before attaching it to the dicing structure and wherein attaching the wafer to the support layer comprises attaching the wafer to the singulated support layer. In some embodiments, attaching the support layer to the dicing structure comprises attaching the support layer to the dicing structure before attaching the wafer to the support layer. In some embodiments, attaching the wafer to the support layer comprises attaching the wafer to the support layer before attaching the support layer to the dicing structure. In some embodiments, the support layer comprises a porous material.

In another embodiment, a method of forming a microelectronic assembly is disclosed. The method can include: attaching a support layer to a dicing structure; attaching a wafer to the support layer; singulating the wafer and the support layer to form a plurality of semiconductor die components, wherein each of the plurality of semiconductor die components comprises a thinned die and a support layer section stacked together; detaching each of the plurality of semiconductor die components from the dicing tape; attaching each of the plurality of semiconductor die components to a substrate such that each of the thinned dies is interposed between the substrate and the corresponding support layer section and such that bonding surfaces of each of the thinned dies are directly bonded to the substrate without an intervening adhesive; and detaching the support layer sections from each of the thinned dies to expose a back surface of each of the thinned dies.

In some embodiments, the method includes singulating the wafer before singulating the support layer. In some embodiments, the method includes singulating the wafer and the support layer in a single dicing process. In some embodiments, singulating the support layer comprises singulating the support layer before attaching it to the dicing structure and wherein attaching the wafer to the support layer comprises attaching the wafer to the singulated support layer. In some embodiments, attaching the support layer to the dicing structure comprises attaching the support layer to the dicing structure before attaching the wafer to the support layer. In some embodiments, attaching the wafer to the support layer comprises attaching the wafer to the support layer before attaching the support layer to the dicing structure. In some embodiments, the method includes depositing a protective layer on a surface of the wafer before singulating the wafer and the support layer. In some embodiments, the method includes after forming the plurality of semiconductor die components, removing the protective layer from each of the plurality of semiconductor die components to expose the bonding surfaces.

In another embodiment, a method of forming a microelectronic assembly is disclosed. The method can include: attaching a handle to a first surface of a wafer; attaching a support layer to a second surface of the wafer; singulating the support layer to form a plurality of support layer sections; attaching a dicing structure to the plurality of support layer sections; detaching the handle from the first surface of the wafer; singulating the wafer to form a plurality of thinned dies, wherein each of the plurality of thinned dies is stacked with one of the plurality of support layer sections to form a plurality of semiconductor die components; detaching each of the plurality of semiconductor die components from the dicing structure; attaching each of the plurality of semiconductor die components onto a substrate such that each of the thinned dies is interposed between the substrate and the corresponding support layer section and such that the first surface of each of the thinned dies is directly bonded to the substrate without an intervening adhesive; and detaching the support layer sections from each of the thinned dies to expose the second surfaces of the thinned dies.

In some embodiments, the method includes detaching the support layer sections from each of the thinned dies without contacting the second surfaces of the thinned dies. In some embodiments, the method includes after detaching the handle from the first surface of the wafer, preparing the first surface for bonding. In some embodiments, preparing the first surface for bonding comprises planarizing the first surface. In some embodiments, preparing the first surface for bonding comprises activating the first surface. In some embodiments, activating the first surface comprises exposing the bonding surface to a nitrogen-containing plasma.

In another embodiment, a semiconductor device component is disclosed. The component can include: a thinned die, wherein the thinned die comprises opposing first and second surfaces, the first surface comprising a planarized bonding surface configured for direct bonding to a substrate without an adhesive; and a support layer attached to the second surface, wherein the semiconductor device component is configured to be attached to the substrate such that the first surface is directly bonded to the substrate and wherein the support layer is configured to be removed from the second surface after the first surface is directly bonded to the substrate.

In some embodiments, the first surface comprises an embedded conductive portion and a planar non-conductive portion. In some embodiments, the support layer is thicker than the thinned die. the second surface comprises a planarized surface with markings indicative of a thinning process. In some embodiments, the second surface comprises a dielectric layer. In some embodiments, the second surface comprises an inorganic dielectric layer. In some embodiments, the inorganic dielectric layer comprises silicon oxide. In some embodiments, the second surface comprises a back-end-of-line (BEOL) metallization layer. In some embodiments, the second surface comprises exposed ends of a plurality of through substrate vias (TSVs). In some embodiments, the die is thinner than 50 microns. In some embodiments, the die is thinner than 30 microns

In another embodiment, a structure can include: a die having a bonding surface bonded to a substrate without an adhesive, the die having a back surface opposite the bonding surface; and a support layer having a first surface opposite a second surface, the second surface attached to a dicing frame, wherein the back surface of the die is attached to the first surface of the support layer.

In some embodiments, the support layer is thicker than the die. In some embodiments, the die is thinner than 50 microns. In some embodiments, the die is thinner than 30 microns. In some embodiments, the bonding surface of the die is directly bonded to the substrate without an adhesive.

In another embodiment, a structure can include: a support layer having a first surface opposite a second surface; and a die having a bonding surface opposite a back surface, the back surface of the die attached to the first surface of the support layer, the second surface of the support layer attached to a dicing frame.

In another embodiment, a method for bonding a die to a substrate is disclosed. The method can include: forming a support layer having a first surface opposite a second surface; providing a die having a bonding surface opposite a back surface, with the back surface of the die attached to the first surface of the support layer; and attaching the second surface of the support layer attached to a dicing frame.

In some embodiments, the method includes directly bonding the die to the substrate without an adhesive.

In another embodiment, a method includes: forming a support layer having a first surface opposite a second surface; forming a die having a bonding surface opposite a back surface, with the back surface of the die attached to the first surface of the support layer; and attaching the second surface of the support layer attached to a dicing frame.

In another embodiment, a semiconductor device component can include: a thinned die, the thinned die comprising opposing first and second surfaces, the first surface comprising a bonding surface bonded to a substrate; and a support layer attached to the second surface of the die, wherein the support is not a semiconductor material and is configured to shield the die from electromagnetic radiation.

In some embodiments, the first surface comprises a planarized bonding surface directly bonded to the substrate without an adhesive.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements.

Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list. Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure. For example, in some embodiments, the descriptions above are implemented in sequential manner following the alpha-numeric ordering. In other embodiments, the steps corresponding to each of the figure labels can be implemented in various ordering, not necessarily in sequential alpha-numeric ordering.

1. A method of forming a microelectronic assembly, the method comprising:
attaching a wafer to a support layer;
singulating the wafer with the support layer attached to a dicing structure to form a plurality of semiconductor die components, each semiconductor die component of the plurality of semiconductor die components having a die and a support layer section of the support layer attached to the die, the support layer section disposed between the die and the dicing structure; and
directly bonding a first semiconductor die component of the plurality of semiconductor die components to a substrate without an intervening adhesive, such that the die is disposed between the substrate and the support layer section.

2. The method of claim 1, further comprising, after the directly bonding, removing the support layer section from the die.

3. The method of claim 2, further comprising:
providing a second semiconductor die component having a second die and a second support layer section attached to the second die; and
after the removing, directly bonding the second die to the die without an adhesive such that the second die is disposed between the die and the second support layer section.

4. The method of claim 1, further comprising, after attaching the wafer to the support layer, attaching the support layer to the dicing structure.

5. The method of claim 1, further comprising, before attaching the wafer to the support layer, attaching the support layer to the dicing structure.

6. The method of claim 1, further comprising singulating the wafer before singulating the support layer.

7. The method of claim 1, further comprising singulating the wafer and the support layer in a single dicing process.

8. The method of claim 1, further comprising dicing the support layer into a plurality of support layer sections before attaching the support layer to the dicing structure.

9. The method of claim 1, further comprising, before the singulating, providing a protective layer over a bonding surface of the wafer.

10. (canceled)

11. The method of claim 9, further comprising, before providing the protective layer, forming the bonding surface, forming the bonding surface comprising planarizing the wafer.

12. (canceled)

13. (canceled)

14. (canceled)

15. The method of claim 1, further comprising, before directly bonding, removing the first semiconductor die component from the dicing structure and flipping the first semiconductor die component such that a bonding surface of the die faces the substrate.

16. The method of claim 1, further comprising providing the support layer, the support layer comprising an ultraviolet (UV) release polymer sheet or a thermal release polymer sheet.

17. The method of claim 1, further comprising providing the support layer, the support layer comprising a porous support layer.

18. (canceled)

19. The method of claim 1, wherein attaching the wafer to the support layer comprises attaching the wafer to the support layer with an adhesive, wherein the adhesive comprises an ultraviolet (UV) adhesive configured to lose adhesion after being exposed to UV radiation, the method comprising detaching the support layer section from the die by exposing the adhesive to UV radiation.

20. (canceled)

21. (canceled)

22. A method of forming a microelectronic assembly, the method comprising:
attaching a support layer to a dicing structure;
attaching a wafer to the support layer;
providing a protective layer on the wafer;
singulating the wafer, the protective layer, and the support layer to form a semiconductor die component having a thinned die and a support layer section stacked together;
removing the protective layer from the semiconductor die component to expose a bonding surface of the thinned die;
detaching the semiconductor die component from the dicing structure;
attaching the semiconductor die component to a substrate such that the thinned die is interposed between the support layer section and the substrate and the bonding surface of the thin die is directly bonded to the substrate without an intervening adhesive; and
after attaching the semiconductor die component to the substrate, detaching the support layer section from the thinned die to expose a back surface of the thinned die.

23. The method of claim 22, wherein singulating the wafer, the protective layer, and the support layer comprises forming a second semiconductor die component having a second thinned die and a second support layer section stacked together.

24. The method of claim 23 further comprising:
removing the protective layer from the second semiconductor die component to expose a bonding surface of the second thinned die;
detaching the second semiconductor component from the dicing tape and attaching it to the substrate such that the second thinned die is interposed between the second support layer section and the substrate, and the bonding surface of the second thinned die is directly bonded to the substrate without an intervening adhesive; and
detaching the second support layer section from the second thinned die to expose a back surface of the second thinned die.

25. The method of claim 22 further comprising:
providing a second semiconductor die component having a second thinned die and a second support layer section attached to the second thinned die; and
directly bonding the second thinned die to the thinned die without an adhesive such that the second thinned die is disposed between the thinned die and the second support layer section.

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. A method of forming a microelectronic assembly, comprising:
attaching a support layer to a dicing structure;
attaching a wafer to the support layer;
singulating the wafer and the support layer to form a plurality of semiconductor die components, wherein each of the plurality of semiconductor die components comprises a thinned die and a support layer section stacked together;
detaching each of the plurality of semiconductor die components from the dicing structure;
attaching each of the plurality of semiconductor die components to a substrate such that each of the thinned dies is interposed between the substrate and a corresponding support layer section and such that bonding surfaces of each of the thinned dies are directly bonded to the substrate without an intervening adhesive; and
detaching the support layer sections from each of the thinned dies to expose a back surface of each of the thinned dies.

39. The method of claim 38, further comprising singulating the wafer before singulating the support layer.

40. The method of claim 38, further comprising singulating the wafer and the support layer in a single dicing process.

41.-73. (canceled)
